(19) United States
(12) Patent Application Publication
(10) Pub. No.: US 2023/0223933 A1
(43) Pub. Date: Jul. 13, 2023

(54) PARALLELED TRANSISTOR CELLS OF POWER SEMICONDUCTOR DEVICES

(71) Applicant: Microchip Technology Incorporated, Chandler, AZ (US)

(72) Inventor: Perry Schugart, West Chester, PA (US)

(21) Appl. No.: 18/153,002

(22) Filed: Jan. 11, 2023

Related U.S. Application Data
(60) Provisional application No. 63/266,655, filed on Jan. 11, 2022.

(51) Int. Cl. H03K 3/012; H01L 29/16; H01L 29/06; H01L 29/78

(52) U.S. Cl. CPC H03K 3/012; H01L 29/0696; H01L 29/1608; H01L 29/7802

(57) ABSTRACT

An apparatus is disclosed that includes a common drain, a common source, and a common gate, respectively, of the power semiconductor device, and paralleled transistor cells of the power semiconductor device. In various examples, a configuration of a gate structure of a first respective transistor cell coupled with the common gate is different than a configuration of a gate structure of a second respective transistor cell coupled with the common gate. Alternatively or additionally, in various examples, a configuration of a structure coupled between a first portion of the paralleled transistor cells and the common gate is different than a configuration of a structure coupled between the second portion of the paralleled transistor cells and the common gate.

### CROSS-REFERENCE TO RELATED APPLICATION

This application claims priority to commonly owned U.S. Provisional Pat. Application Serial No. 63/266,655, filed Jan. 11, 2022, the contents and disclosure of which is incorporated herein in its entirety by this reference.

### TECHNICAL FIELD

One or more examples relate to power semiconductor devices, and paralleled transistor cells of power semiconductor devices. Some examples relate to turning OFF transistor cells of power semiconductor devices, and turning off power semiconductor devices more generally.

### BACKGROUND

Silicon Carbide (SiC) transistors (e.g., power MOSFETs) switch faster than Silicon transistors but may carry secondary effects such as noise, electromagnetic interference, overvoltage, overheating, and short circuit. Applications using high speed switches such as SiC MOSFETs need to manage these secondary effects to meet radiated emission requirements, meet cost targets, and protect the MOSFET from damage. Increased turn-OFF time may reduce these secondary effects but conventional methods to slow switching speed may add components and cost to the device, and reduce efficiency.

### BRIEF DESCRIPTION OF THE DRAWINGS

FIG. 1 is a block diagram depicting an apparatus, in accordance with one or more examples of the present disclosure.

FIG. 2 is a block diagram depicting an apparatus, in accordance with one or more examples.

FIG. 3 is a block diagram depicting possible configurations of a first structure and a second structure, in accordance with one or more examples.

FIG. 4 is a block diagram depicting possible configurations of a first structure and second structure, in accordance with one or more examples.

FIG. 5 is a block diagram depicting possible configurations of a first structure and second structure, in accordance with one or more examples.

FIG. 6 is a block diagram depicting a response of structures to a stimulus, in accordance with one or more examples.

FIGS. 7A, 7B, 7C, and 7D are schematic diagrams depicting an example SiC MOSFET die in progressively more detailed views, in accordance with one or more examples.

FIG. 8 is a flowchart depicting a method of turning off a power semiconductor device, in accordance with one or more examples of the present disclosure.

### DETAILED DESCRIPTION

In the following detailed description, reference is made to the accompanying drawings, which form a part hereof, and in which are shown, by way of illustration, specific examples in which the present disclosure may be practiced. These examples are described in sufficient detail to enable a person of ordinary skill in the art to practice the present disclosure. However, other examples enabled herein may be utilized, and structural, material, and process changes may be made without departing from the scope of the disclosure.

The illustrations presented herein are not meant to be actual views of any particular method, system, device, or structure, but are merely idealized representations that are employed to describe the examples of the present disclosure. In some instances similar structures or components in the various drawings may retain the same or similar numbering for the convenience of the reader; however, the similarity in numbering does not necessarily mean that the structures or components are identical in size, composition, configuration, or any other property.

The following description may include examples to help enable one of ordinary skill in the art to practice the disclosed examples. The use of the terms “exemplary,” “by example,” and “for example,” means that the related description is explanatory, and though the scope of the disclosure is intended to encompass the examples and legal equivalents, the use of such terms is not intended to limit the scope of an example or this disclosure to the specified components, steps, features, functions, or the like.

It will be readily understood that the components of the examples as generally described herein and illustrated in the drawings could be arranged and designed in a wide variety of different configurations. Thus, the following description of various examples is not intended to limit the scope of the present disclosure, but is merely representative of various examples. While the various aspects of the examples may be presented in the drawings, the drawings are not necessarily drawn to scale unless specifically indicated.

Furthermore, specific implementations shown and described are only examples and should not be construed as the only way to implement the present disclosure unless specified otherwise herein. Elements, circuits, and functions may be shown in block diagram form in order not to obscure the present disclosure in unnecessary detail. Conversely, specific implementations shown and described are exemplary only and should not be construed as the only way to implement the present disclosure unless specified otherwise herein. Additionally, block definitions and partitioning of logic between various blocks is exemplary of a specific implementation. It will be readily apparent to one of ordinary skill in the art that the present disclosure may be practiced by numerous other partitioning solutions. For the most part, details concerning timing considerations and the like have been omitted where such details are not necessary to obtain a complete understanding of the present disclosure and are within the abilities of persons of ordinary skill in the relevant art.

Those of ordinary skill in the art will understand that information and signals may be represented using any of a variety of different technologies and techniques. Some drawings may illustrate signals as a single signal for clarity of presentation and description. It will be understood by a person of ordinary skill in the art that the signal may represent a bus of signals, wherein the bus may have a variety of bit widths and the present disclosure may be implemented on any number of data signals including a single data signal.

The various illustrative logical blocks, modules, and circuits described in connection with the examples disclosed herein may be implemented or performed with a general purpose processor, a special purpose processor, a digital signal processor (DSP), an Integrated Circuit (IC), an Application Specific Integrated Circuit (ASIC), a Field Programmable Gate Array (FPGA) or other programmable logic device, discrete gate or transistor logic, discrete hardware components, or any combination thereof designed to perform the functions described herein. A general-purpose processor (may also be referred to herein as a host processor or simply a host) may be a microprocessor, but in the alternative, the processor may be any conventional processor, controller, microcontroller, or state machine. A processor may also be implemented as a combination of computing devices, such as a combination of a DSP and a microprocessor, a plurality of microprocessors, one or more microprocessors in conjunction with a DSP core, or any other such configuration. A general-purpose computer including a processor is considered a special-purpose computer while the general-purpose computer is to execute computing instructions (e.g., software code) related to examples of the present disclosure.

The examples may be described in terms of a process that is depicted as a flowchart, a flow diagram, a structure diagram, or a block diagram. Although a flowchart may describe operational acts as a sequential process, many of these acts can be performed in another sequence, in parallel, or substantially concurrently. In addition, the order of the acts may be re-arranged. A process may correspond to a method, a thread, a function, a procedure, a subroutine, a subprogram, other structure, or combinations thereof. Furthermore, the methods disclosed herein may be implemented in hardware, software, or both. If implemented in software, the functions may be stored or transmitted as one or more instructions or code on computer-readable media. Computer-readable media includes both computer storage media and communication media including any medium that facilitates transfer of a computer program from one place to another.

Any reference to an element herein using a designation such as “first,” “second,” and so forth does not limit the quantity or order of those elements, unless such limitation is explicitly stated. Rather, these designations may be used herein as a convenient method of distinguishing between two or more elements or instances of an element. Thus, a reference to first and second elements does not mean that only two elements may be employed there or that the first element must precede the second element in some manner. In addition, unless stated otherwise, a set of elements may include one or more elements.

As used herein, the term “substantially” in reference to a given parameter, property, or condition means and includes to a degree that one of ordinary skill in the art would understand that the given parameter, property, or condition is met with a small degree of variance, such as, for example, within acceptable manufacturing tolerances. By way of example, depending on the particular parameter, property, or condition that is substantially met, the parameter, property, or condition may be at least 90% met, at least 95% met, or even at least 99% met.

Silicon carbide (SiC) transistors switch faster than silicon (Si) transistors, but often with undesirable secondary effects, such as noise, electromagnetic interference (EMI), overvoltage, overheating, and short circuit, without limitation. Such effects may require additional components and/or slowing the switching speed, which may reduce transistor efficiency and, or, add cost to application.

By resistively decoupling a gate on a portion of the paralleled transistor cells of a power semiconductor device (e.g., MOSFET), more gate charge (Q_{GD}) may be held in the portion of cells, which may delay cell turn-OFF and slow the complete turn-OFF of the power semiconductor device. The power semiconductor device may be better protected from short circuit situations due to dissipation of energy during turn-OFF over a longer duration of time.

Non-limiting examples of advantages of the present disclosure may include simplifying gate drive (e.g., turn-ON and turn-OFF, without limitation) of SiC MOSFETs, which may increase performance and reduce cost. Lower cost may be a result of elimination or reduction of filter components added to address secondary effects. Further non-limiting examples of advantages may include higher performance as compared with generally slowing down the switching of a device, which slowing down may add heat to the device. A further yet non-limiting example advantage may include higher reliability due to increased short circuit survivability.

By selectively delaying turn-OFF of a certain portion of paralleled transistor cells of a power semiconductor device, a softer turn-OFF of the device is provided, which may reduce the high speed switching effects and susceptibility to short circuit damage. By providing softer turn-OFF of the power semiconductor device, voltage overshoot, voltage ringing, and current ringing may be reduced (as compared to faster turn-OFF), and short circuit survivability may increase. In one or more examples, a change in effective gate resistance, gate capacitance, or both, may optionally delay turn-OFF of a portion of cells of the power semiconductor device to reduce the high speed switching effects and susceptibility to short circuit damage.

There is a relationship between gate-drain charge (Q_{GD}) and drain-source voltage across a MOSFET (V_{DS}) that may increase MOSFET turn-OFF time. At high voltage levels of drain-source voltage V_{DS}, drain-source voltage V_{DS} influences gate-drain charge Q_{GD} to increase MOSFET turn-OFF time. The turn-OFF time of a MOSFET thus increases as drain-source voltage V_{DS} increases. Further, disclosed techniques may not affect or impact turn-ON time, but may only increase turn-OFF time.

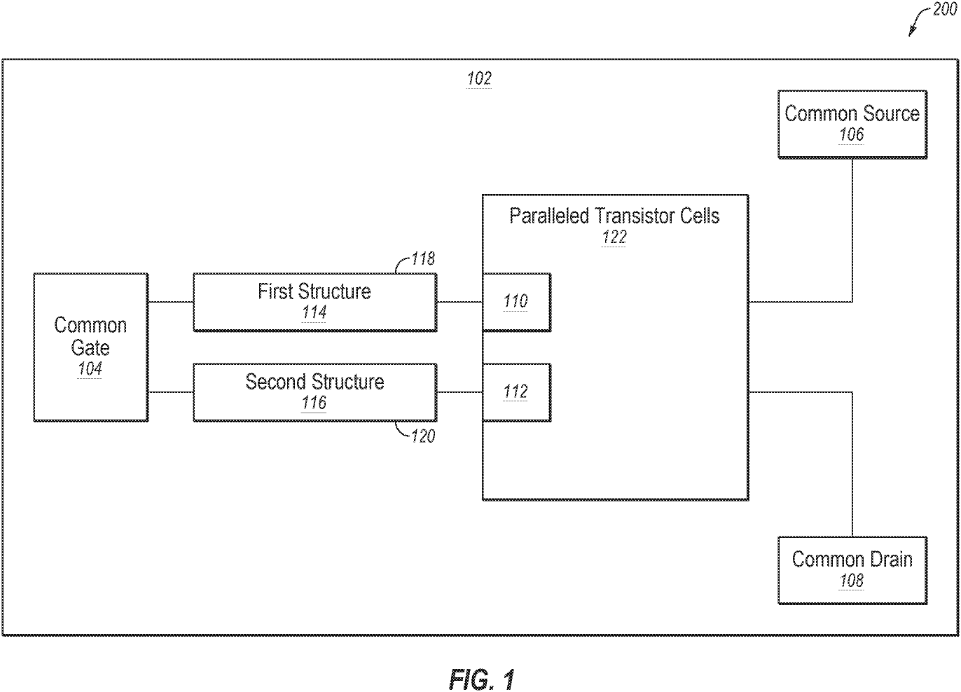

FIG. 1 is a block diagram depicting an example apparatus 100, in accordance with one or more examples of the present disclosure. The apparatus 100 is or includes a power semiconductor device 102 that may exhibit increased turn-OFF time in accordance with one or more examples, discussed below.

Power semiconductor device 102 includes a common gate 104, a common source 106, a common drain 108, and paralleled transistor cells 122. As non-limiting examples, power semiconductor device 102 may be a Silicon Carbide (SiC) semiconductor device, such as a power metal-oxide-semiconductor field-effect transistor (MOSFET).

Generally speaking, respective gates of transistor cells of paralleled transistor cells 122 are operatively coupled to common gate 104. Respective sources of transistor cells of paralleled transistor cells 122 are operatively coupled to common source 106. Respective drains of transistor cells of paralleled transistor cells 122 are operatively coupled to a common drain 108.

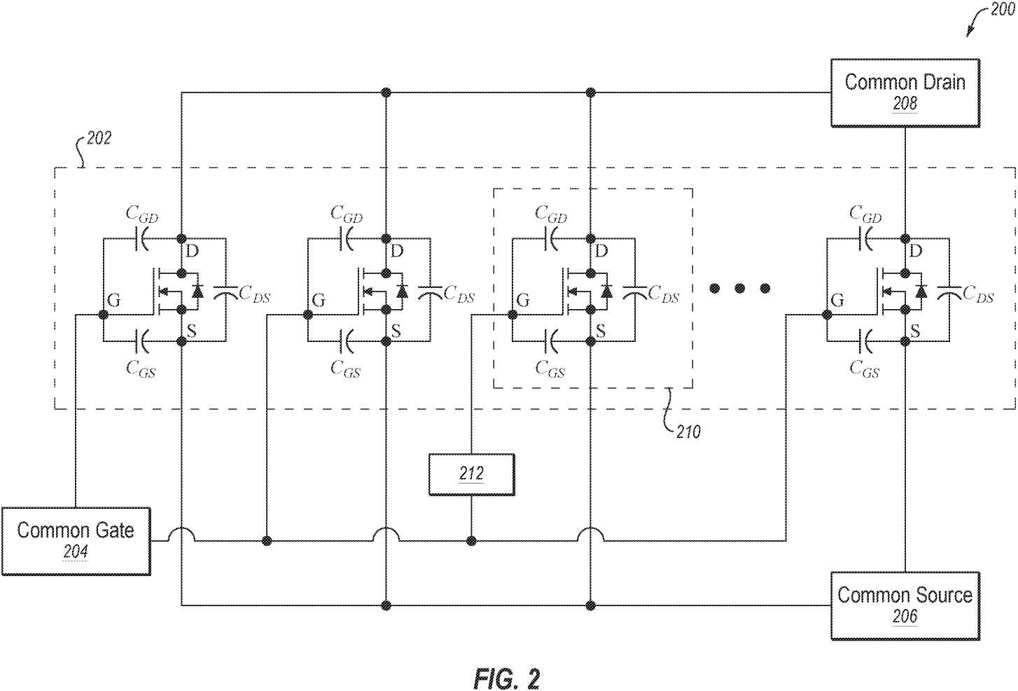

Respective gates (respective gates and couplings not depicted in FIG. 1, but depicted in FIG. 2) of a first portion 110 of paralleled transistor cells 122 are operatively coupled to common gate 104 via first structure 114. Respective gates (respective gates and couplings not depicted in FIG. 1, but depicted in FIG. 2) of a second portion 112 of paralleled transistor cells 122 are operatively coupled to common gate 104 via second structure 116.

In one or more examples, one or more of the first portion 110 of paralleled transistor cells 122 and the second portion 112 of paralleled transistor cells 122 may respectively include one or more respective transistor cells of paralleled transistor cells 122, and connections to respective gates thereof. Additionally or alternatively, in one or more examples, one or more of first structure 114 or second structure 116 may include material of respective gate structures or portions of gate structures of one or more transistor cells of paralleled transistor cells 122 in first portion 110 or second portion 112, in which case, first portion 110 of paralleled transistor cells 122 may include first structure 114 and second portion 112 of paralleled transistor cells 122 may include second structure 116. In various examples, structures operatively coupling common gate to respective portions of paralleled transistors may include use of intermediate structures, respective gate materials of transistor cells, respective dimensions of gate structure of gates of transistor cells, and combinations and sub-combinations of the same, without exceeding the scope of this disclosure.

First structure 114 and the second structure 116 may respectively exhibit a configuration, which configurations are described in more detail below with respect to examples depicted by FIGS. 2-4. A configuration 118 exhibited by first structure 114 may be different than a configuration 120 exhibited by second structure 116, as discussed below.

Respective configurations 118 and 120 of first structure 114 and second structure 116 may be set, or predetermined to set, a respective resistance or capacitance of first structure 114 and second structure 116, respectively. Respective resistances or capacitances of first structure 114 and second structure 116 may affect respective effective gate resistances or gate capacitances of transistor cells of first portion 110 of paralleled transistor cells 122 and respective effective gate resistances or capacitances of transistor cells of second portion 112 of paralleled transistor cells 122. Effective gate resistance or capacitance may be set (e.g., via respective resistances or capacitances of first structure 114 or second structure 116, without limitation) to selectively influence rate of change of gate-drain charge Q_{GD} of respective transistor cells of first portion 110 and second portion 112 of paralleled transistor cells 122. A rate-of-change of a gate-drain charge Q_{GD} of respective transistor cells of first portion 110 and, or, second portion 112 of paralleled transistor cells 122 may be set to determine a turn-OFF time of power semiconductor device 102. As a non-limiting example, rate-of-change of the gate-drain charge may be set via a respective resistance or capacitance of first structure 114 or second structure 116, or via resistance or capacitance of a gate structure as discussed below.

Use of additional structures with different configurations than first structure 114 or second structure 116 to couple common gate 104 with respective gates of transistor cells of first portion 110, second portion 112, or further portions of paralleled transistor cells 122 different than first portion 110 and second portion 112, is specifically contemplated and does not exceed the scope of this disclosure. Numbers of structures and gates of transistor cells coupled by such structures with a common gate is a matter of design choice based on specific operating conditions.

FIG. 2 is a block diagram depicting an apparatus 200, in accordance with one or more examples. Apparatus 200 is a non-limiting example of a power semiconductor device 102 of FIG. 1, and so may also be referred to herein as “a power semiconductor device 200.”

Apparatus 200 includes paralleled transistor cells 202, common gate 204, common source 206, and common drain 208. Apparatus 200 further includes structure 212 that operatively couples common gate 204 with a first portion 210 of paralleled transistor cells 202.

Although FIG. 2 depicts structure 212 outside the block that represents paralleled transistor cells 202, it should be understood that structure 212 may be separate from paralleled transistor cells 202 or included or integrated with paralleled transistor cells 202, without exceeding the scope of this disclosure. As non-limiting examples, paralleled transistor cells 202 may include structure 212, or a structure that forms some or a totality of paralleled transistor cells 202 may include structure 212.

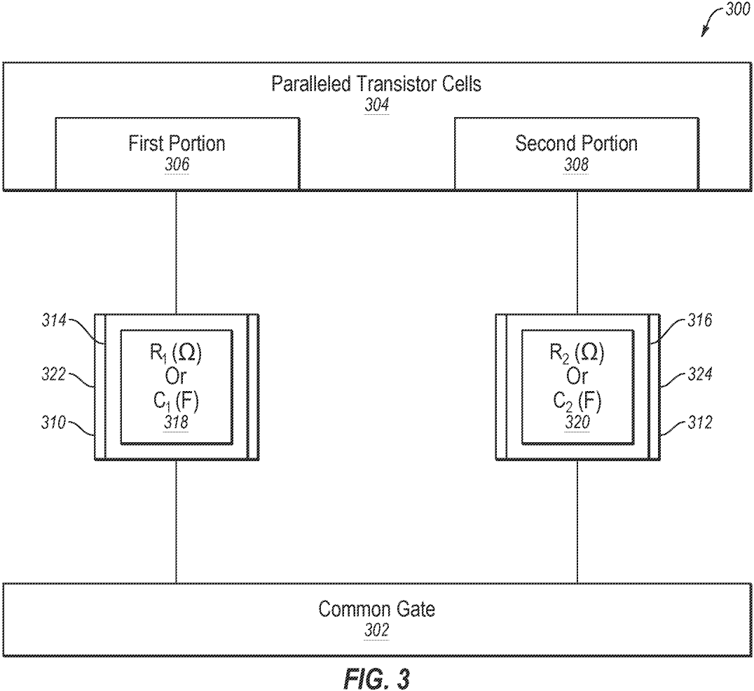

FIG. 3 is a block diagram depicting example configuration of a structure (e.g., first structure 114 or second structure 116 of FIG. 1, or structure 212 of FIG. 2, without limitation) to operatively couple a common gate (e.g., common gate 104 of FIG. 1, or common gate 204 of FIG. 2, without limitation) with one or more respective gates of paralleled transistor cells (e.g., paralleled transistor cells 122 of FIG. 1, or paralleled transistor cells 202 of FIG. 2, without limitation), in accordance with one or more examples.

Apparatus portion 300 includes common gate 302, paralleled transistor cells 304, first structure 310 and second structure 312. Paralleled transistor cells 304 includes first portion 306 and second portion 308, which are respectively coupled with common gate 302 by first structure 310 and second structure 312. First structure 310 includes or is formed from first material 318. The geometry and dimension 322 of first structure 310 and the characteristics of first material 318 defines a configuration 314 of first structure 310, which sets a resistance or capacitance exhibited by first structure 310, represented in FIG. 3 by R₁. Second structure 312 includes or is formed from second material 320. The geometry and dimension of 324 of second structure 312 and the characteristics of second material 320 defines a configuration 316 of second structure 312, which sets a resistance or capacitance exhibited by second structure 312, represented in FIG. 3 by R₂. Resistance R₁ and R₂ may be measured in ohm (Q). In one or more examples, first material 318 may exhibit a resistivity that is the same or different than a resistivity exhibited by second material 320.

Resistance R₁ and R₂ (or capacitance C₁ and C₂) are different, though at least one of resistance R₁ and R₂ (or capacitance C₁ and C₂) may be substantially the same as the resistance or capacitance of portions of other coupling between common gate and respective gates of paralleled transistors (not depicted). In one or more examples, the first resistance R₁ may be greater than the second resistance R₂ (or a first capacitance C₁ may be greater than a second capacitance C₂) and in other examples, the first resistance R₁ may be less than the second resistance R₂ (or a first capacitance C₁ may be less than a second capacitance C₂). The difference in resistance or capacitance exhibited by first structure 310 and second structure 312 may result in different resistance or capacitance (e.g., more or less resistance or capacitance, without limitation) between transistor cells associated with first portion 306 of paralleled transistor cells 304 and common gate 302, as compared to other transistor cells associated with second portion 308 of paralleled transistor cells 304 and common gate 302.

When resistance or capacitance between first portion 306 of paralleled transistor cells 304 and common gate 302 is increased, influence of drain-source voltage on rate-of-change of associated gate-drain charge Q_{GD} increases for respective transistor cells of the first portion of paralleled transistor cells, and cell turn-OFF time may be increased (which may also be characterized as slowing cell turn-OFF), which may slow complete turn-OFF of a respective power semiconductor device (e.g., power semiconductor device 102).

A given cell turn-OFF time or power semiconductor device turn-OFF time is a matter of design choice based on specific operating conditions.

Increasing turn-OFF time (which may also be characterized as slowing turn-OFF), and dissipating energy during turn-OFF over a longer time duration (compared to circuits that do not include discussed structures operatively coupling a common gate to a portion of a paralleled transistor cells), may reduce undesirable affects associated with shorter turn-OFF times, such as noise, electromagnetic interference, overvoltage (i.e., voltage outside a specified operating range), overheating (i.e., temperature outside a specified operating range), or short circuits, without limitation.

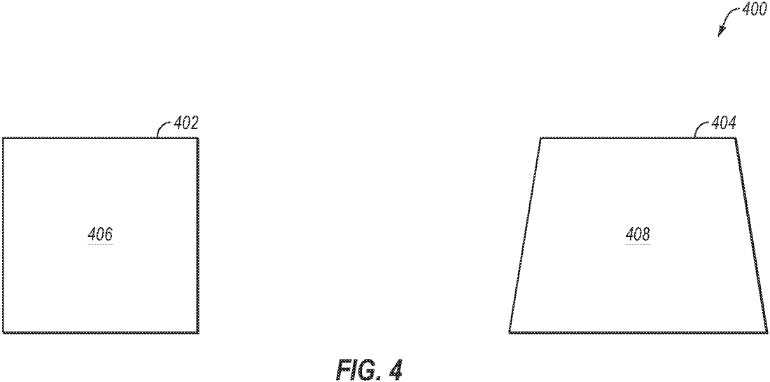

FIG. 4 is another block diagram 400 depicting possible configurations of a first structure (e.g., first structure 114) and second structure (e.g., second structure 116), in accordance with one or more examples. In one or more examples, a configuration of the first structure 406 (e.g., configuration 118 corresponding to first structure 114) may comprise a first shape 402. A configuration of the second structure 408 (e.g., configuration 120 corresponding to second structure 116) may comprise a second shape 404, that is different than the first shape 402. One of ordinary skill in the art will appreciate that the present disclosure is not limited to the particular shapes depicted in FIG. 4 (e.g., a square or a trapezoid) but that any shape may be used. In some instances, the shapes depicted in FIG. 4 may represent a cross-sectional view of the structures (e.g., first structure 114 and second structure 116) that operatively couple paralleled transistor cells (e.g., paralleled transistor cells 122) and common gate (e.g., common gate 104). The difference in shape, such as the difference between first shape 402 and second shape 404, may result in different resistance or capacitance exhibited by structures having the different shapes (e.g., first structure 114 exhibits more or less resistance or capacitance than second structure 116, without limitation) between one or more paralleled transistor cells (e.g., first portion 110, without limitation) and a common gate (e.g., common gate 104), as compared to other paralleled transistor cells (e.g., second portion 112) and the common gate.

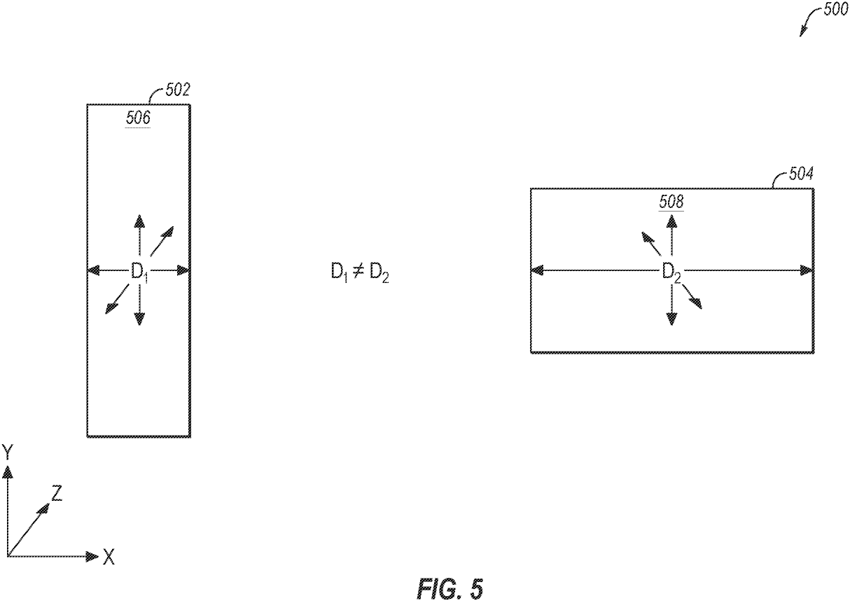

FIG. 5 is yet another block diagram depicting configurations 500 of a first structure (e.g., first structure 114) and second structure (e.g., second structure 116), in accordance with one or more examples.

In one or more examples, a configuration of the first structure 506 may comprise a first dimensions 502, represented by D₁. A configuration of the second structure 508 (e.g., configuration 120 corresponding to second structure 116) may comprise a second dimensions 504, represented by D₂. First dimensions 502 (D₁) may be different than the second dimensions 504 (D₂), as depicted in FIG. 5. In one or more examples, at least one of dimensions D₁ is greater than at least one of dimensions D₂, while in other examples, dimensions D₁ is less than dimensions D₂. The difference in dimension, such as the difference between first dimensions 502 and second dimensions 504, may result in different resistance or capacitance (e.g., more or less resistance or capacitance, without limitation) between one or more paralleled transistor cells (e.g., first portion 110) and a common gate (e.g., common gate 104), as compared to other paralleled transistor cells (e.g., second portion 112) and the common gate. For example, to set the resistance or capacitance of first structure 506 to be greater than the resistance or capacitance of second structure 508, dimensions D₁ may be less than dimensions D₂.

Additional resistance or capacitance between one or more paralleled transistor cells and the common gate as compared to other paralleled transistor cells and the common gate may be obtained as a result of any combination of different materials, shapes, and/or dimensions. Accordingly, any combination of different materials, shapes, and/or dimensionalities may be used to obtain such additional resistance or capacitance.

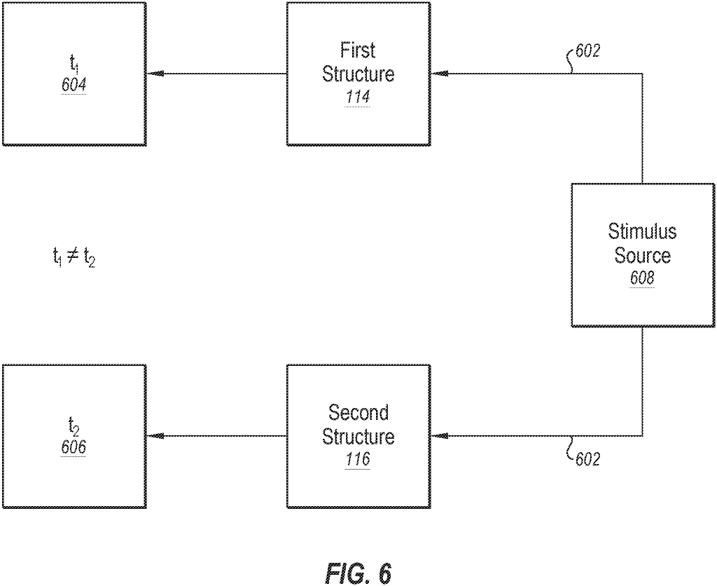

FIG. 6 is a block diagram depicting respective responses of structures (e.g., a first structure 114 and a second structure 116) to a stimulus (e.g., stimulus 602), in accordance with one or more examples. In one or more examples, stimulus 602 is the gate-drain charge Q_{GD} of a respective transistor cell.

A stimulus 602 generated by stimulus source 608 may be an electrical stimulus applied equally to the first structure 114 and to the second structure 116. Stimulus source 608 may be the common gate.

The timing 604 represents the response of the first structure 114 to the stimulus 602, and is also represented by t₁. The timing 606 represents the response of the second structure 116 to the stimulus 602, and is also represented by t₂. timing 604 (t₁) and timing 606 (t₂) may not be equal, even though first structure 114 and second structure 116 are provided with the same stimulus 602.

In some instances, t > t₂, and in other instances, t₁ < t₂. By way of example, the difference between timing 604 and timing 606 may be attributable to the differences in the configurations shown in FIGS. 2-4, namely differences in material (i.e., resistivity), shape, and/or dimensions. Furthermore, the difference between timing 604 and timing 606 may be due to added resistance or capacitance between a first portion 110 (as compared to a second portion 112) of paralleled transistor cells 122 of the power semiconductor device 102. In one or more embodiments, the timing 604 or timing 606 may be non-linear.

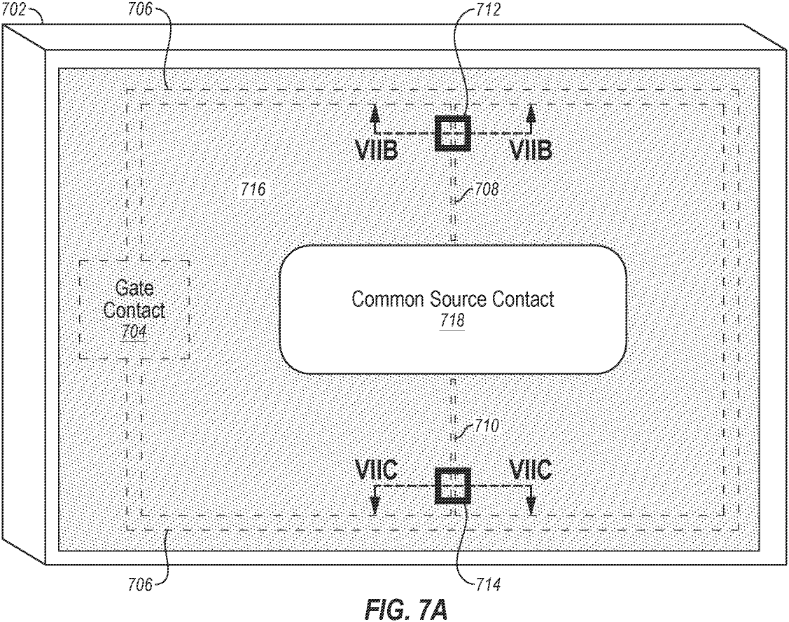

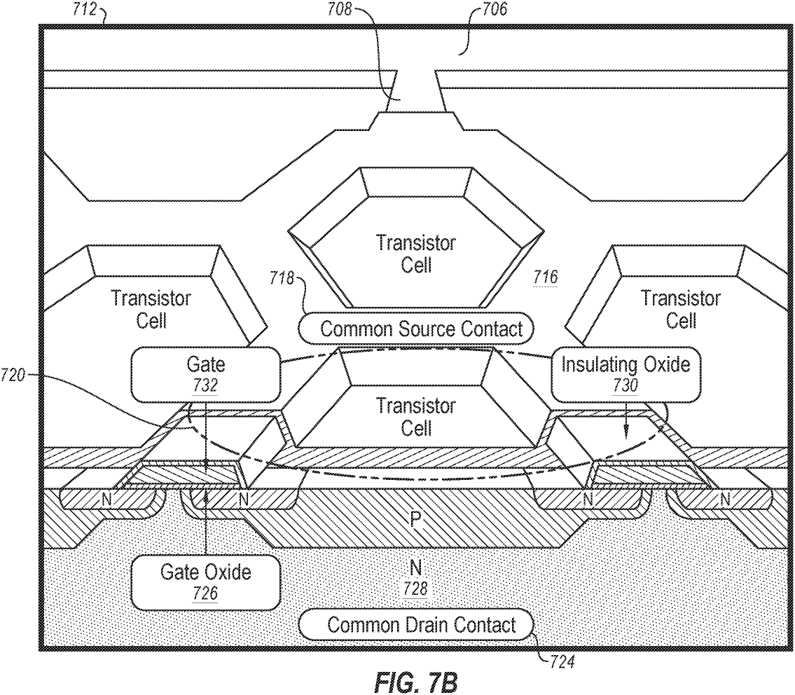

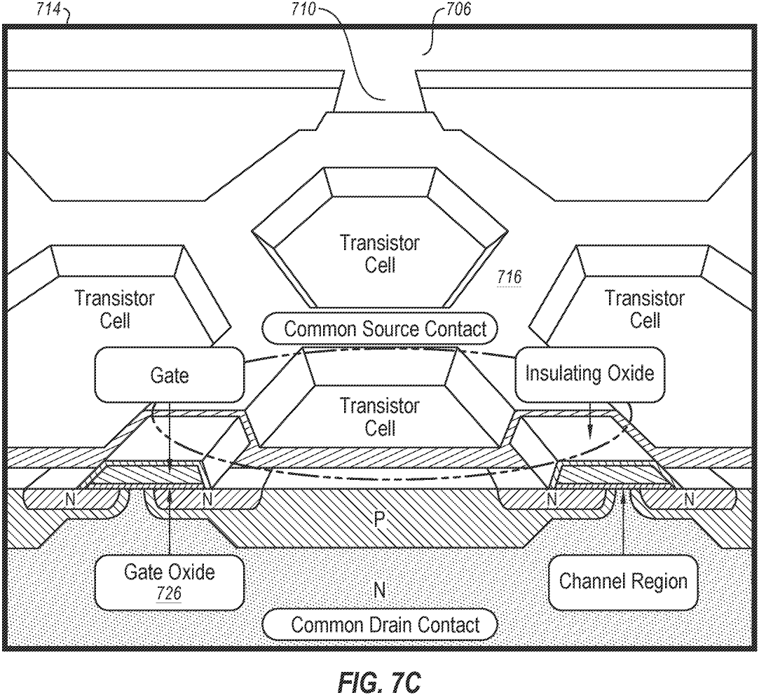

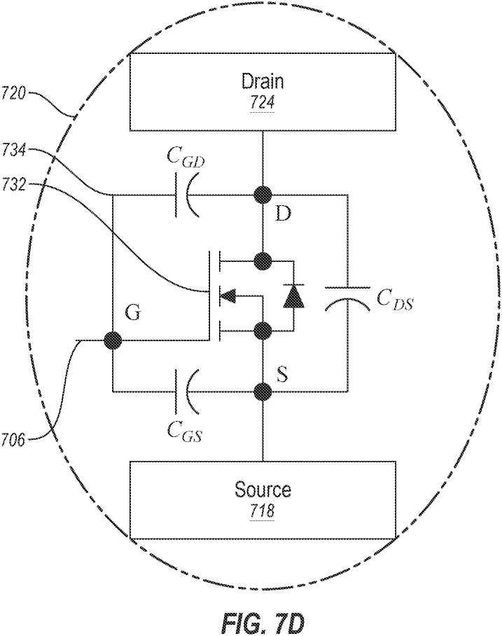

FIGS. 7A, 7B, 7C, and 7D are schematic diagrams depicting an example SiC MOSFET die in progressively more detailed views. FIG. 7A is a schematic diagram depicting an isometric projection of a SiC MOSFET die 702. FIG. 7B is a schematic diagram of a detailed view of a first portion 712 of SiC MOSFET die 702 taken at a cross-section along dashed-line VIIB depicted in FIG. 7A. FIG. 7C is a schematic diagram of a detailed view of a second portion 714 of SiC MOSFET die 702 taken at a cross-section along dashed-line VIIC depicted in FIG. 7A. FIG. 7D is a schematic diagram depicting a SiC MOSFET transistor cell region 720 of FIGS. 7B or 7C.

Turning to FIG. 7A, SiC MOSFET die 702 includes common gate contact 704, common gate 706, common source contact 718, and common source metallization 716 of paralleled transistor cells, including a first portion 712 and a second portion 714. SiC MOSFET die 702 further includes a first structure 708 and a second structure 710, configured to decrease turn OFF time for transistor cells in first portion 712 through a more resistive configuration of first structure 708 than a configuration of second structure 710, as discussed herein.

Turning to FIG. 7B, first portion 712 includes common gate 706, common source contact 718, common drain 728, common drain contact 724, gate oxide 726, and insulating oxide 730. Common gate 706 may comprise a polysilicon material, which may be referred to as a “gate-poly.” Gate oxide 726 may comprise a dielectric material located to separate material of respective gates of transistor cells from material of common drain 728 and sources of respective transistor cells. Insulating oxide 730 provides insulation for gate structure 732 from surrounding material, which surrounding material may be a metallic, semiconductor or other material that is insulating, without limitation.

Turning to FIG. 7C, second portion 714 includes similar elements as first portion 712 of FIG. 7B, which are not re-described, here. Notably, first structure 708, depicted in FIG. 7B, has smaller dimensions (e.g., width, without limitation) than second structure 710, depicted in FIG. 7C, accordingly, first structure 708 exhibits a more resistive configuration than second structure 710.

One of ordinary skill in the art will appreciate that transistor cell region 720 does not need to have a hexagonal shape, as depicted in FIG. 7, and may exhibit other shapes and configurations without exceeding the scope of this disclosure.

Turning to FIG. 7D, transistor cell region 720 includes transistor cell 720, common source contact 718, and common drain contact 724. Transistor cell 734 includes gate G, drain D, and source S. Gate G of transistor cell 734 is coupled to common gate 706 and includes gate structure 708. Inclusion of gate structures, such as gate structure 708 in one or more transistor cells of SiC MOSFET die 702 is optionally in addition to, or as an alternative to, inclusion of first and second structures coupling portions of paralleled transistor cells to common gate 706 of SiC MOSFET die 702.

In one or more examples, the geometry and dimensions, material, and resistance or capacitance of gate structure 732 may differ from geometry, dimensions, material, and resistance or capacitance of gate structures of gates of other transistor cells of SiC MOSFET die 702, which may result in different (e.g., more or less, without limitation) resistance or capacitance for gate structure 732 and gate resistance or gate capacitance of gate G, or other gates of transistor cells of SiC MOSFET die 702. Additional gate resistance or gate capacitance may increase cell turn OFF time for a transistor cell or multiple transistor cells, as the case may be. The configuration of the material used for gate structure 732 may be tuned or set for a particular device (e.g., SiC MOSFET or power semiconductor device more generally, without limitation) to accomplish desired specifications.

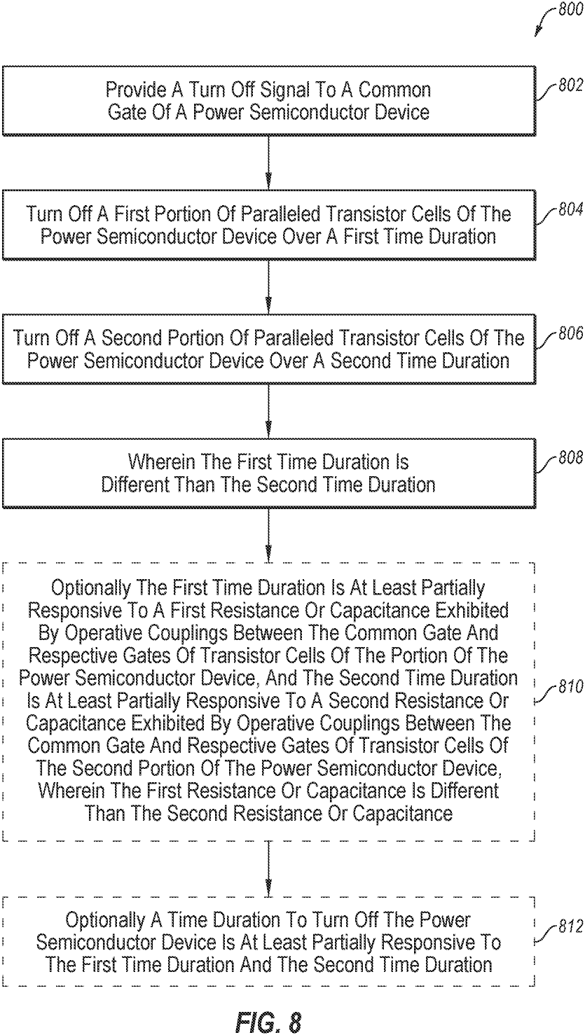

FIG. 8 is a flowchart depicting a method 800 of turning off portions (e.g., first portion 110 and second portion 112) of paralleled transistor cells (e.g., paralleled transistor cells 122) of a power semiconductor device (e.g., power semiconductor device 102), in accordance with one or more examples of the present disclosure. In one or more examples, method 800 may be performed in relation to the power semiconductor device 102 of FIG. 1 or the power semiconductor device 200 of FIG. 2. Although illustrated as discrete blocks, various blocks may be divided into additional blocks, combined into fewer blocks, or eliminated, depending on the desired implementation.

In operation 802, method 800 provides a turn OFF signal to a common gate (e.g., common gate 104) of a power semiconductor device (e.g., power semiconductor device 102).

In operation 804, method 800 turns OFF a first portion (e.g., first portion 110) of paralleled transistor cells (e.g., paralleled transistor cells 122) of the power semiconductor device over a first time duration.

In operation 806, method 800 turns OFF a second portion (e.g., second portion 112) of paralleled transistor cells (e.g., paralleled transistor cells 122) of the power semiconductor device over a second time duration.

According to operation 808, the first time duration may be different than the second time duration.

According to operation 810, which is optional, the first time duration may be at least partially responsive to a first resistance or capacitance exhibited by operative couplings between the common gate and respective gates of the first portion of transistor cells of the power semiconductor device. The second time duration may be at least partially responsive to a second resistance or capacitance exhibited by operative couplings between the common gate and respective gates of the further portion of transistor cells of the power semiconductor device. In one or more examples, the first resistance or capacitance may be different than the second resistance or capacitance.

According to operation 812, which is optional, a time duration to turn off the power semiconductor device may be at least partially responsive to the first time duration and the second time duration.

Notably, the drain-source voltages of gates of respective transistor cells of the first portion of the power semiconductor device are different than drain-source voltages of gates of respective transistor cells of the second portion of the power semiconductor device.

As used in the present disclosure, the terms “module” or “component” may refer to specific hardware implementations to perform the actions of the module or component and/or software objects or software routines that may be stored on and/or executed by general purpose hardware (e.g., computer-readable media, processing devices, etc.) of the computing system. In one or more examples, the different components, modules, engines, and services described in the present disclosure may be implemented as objects or processes that execute on the computing system (e.g., as separate threads). While some of the system and methods described in the present disclosure are generally described as being implemented in software (stored on and/or executed by general purpose hardware), specific hardware implementations or a combination of software and specific hardware implementations are also possible and contemplated.

As used in the present disclosure, the term “combination” with reference to a plurality of elements may include a combination of all the elements or any of various different subcombinations of some of the elements. For example, the phrase “A, B, C, D, or combinations thereof” may refer to any one of A, B, C, or D; the combination of each of A, B, C, and D; and any subcombination of A, B, C, or D such as A, B, and C; A, B, and D; A, C, and D; B, C, and D; A and B; A and C; A and D; B and C; B and D; or C and D.

Terms used in the present disclosure and especially in the appended claims (e.g., bodies of the appended claims) are generally intended as “open” terms (e.g., the term “including” should be interpreted as “including, but not limited to,” the term “having” should be interpreted as “having at least,” the term “includes” should be interpreted as “includes, but is not limited to,” etc.).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” or “one or more of A, B, and C, etc.” is used, in general such a construction is intended to include A alone, B alone, C alone, A and B together, A and C together, B and C together, or A, B, and C together, etc.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

Additional non-limiting examples include:

Example 1: An apparatus, comprising: a common drain, a common source, and a common gate, respectively of a power semiconductor device; and paralleled transistor cells of the power semiconductor device, wherein: a configuration of a gate structure of a first respective transistor cell coupled with the common gate is different than a configuration of a gate structure of a second respective transistor cell coupled with the common gate; or a configuration of a first structure coupled between a first portion of the paralleled transistor cells and the common gate is different than a configuration of a second structure coupled between a second portion of the paralleled transistor cells and the common gate.

Example 2: The apparatus according to Example 1, wherein the first structure, responsive to the configuration of the first structure, exhibits a first capacitance or resistance, and the second structure, responsive to the configuration of the second structure, exhibits a second capacitance or resistance, and wherein the first capacitance or resistance is different than the second capacitance or resistance.

Example 3: The apparatus according to Examples 1 and 2, wherein the configuration of the first structure comprises a first material and the configuration of the second structure comprises a second material, wherein a resistivity exhibited by the first material is different than a resistivity exhibited by the second material.

Example 4: The apparatus according to Examples 1 through 3, wherein the configuration of the first structure comprises a first shape and the configuration of the second structure comprises a second shape.

Example 5: The apparatus according to Examples 1 through 4, wherein the configuration of the first structure comprises a first dimensions and the configuration of the second structure comprises a second dimensions, wherein at least one of the first dimensions and the second dimensions are different.

Example 6: The apparatus according to Examples 1 through 5, wherein the paralleled transistor cells of the power semiconductor device comprise metal-oxide-semiconductor field-effect transistor cells.

Example 7: The apparatus according to Examples 1 through 6, wherein the paralleled transistor cells of the power semiconductor device comprises silicon-carbide (SiC) transistor cells.

Example 8: The apparatus according to Examples 1 through 7, wherein the SiC transistor cells comprise power metal-oxide-semiconductor field-effect transistor cells.

Example 9: The apparatus according to Examples 1 through 8, wherein the first structure is coupled between the common gate and a gate of a transistor cell of the first portion of the paralleled transistor cells, and the second structure is coupled between the common gate and a gate of a transistor cell of the second portion of the paralleled transistor cells.

Example 10: The apparatus according to Examples 1 through 9, wherein a response of the first structure to a stimulus is different than a response of the second structure to a further stimulus.

Example 11: The apparatus according to Examples 1 through 10, wherein the stimulus is a gate-drain charge of a transistor cell of the first portion of the paralleled transistor cells, and the further stimulus is a gate-drain charge of a transistor cell of the second portion of the paralleled transistor cells.

Example 12: The apparatus according to Examples 1 through 11, wherein the response of the first structure sets a rate-of-change in the gate-drain charge of the transistor cell of the first portion of the paralleled transistor cells, and the response of the second structure sets a rate-of-change in gate-drain charge of the transistor cell of the second portion of the paralleled transistor cells.

Example 13: A method, comprising: providing a turn OFF signal to a common gate of a power semiconductor device; turning OFF a first portion of paralleled transistor cells of the power semiconductor device over a first time duration; and turning OFF a second portion of paralleled transistor cells of the power semiconductor device over a second time duration, wherein the first time duration is different than the second time duration.

Example 14: The method according to Example 13, wherein the first time duration is at least partially responsive to a first resistance or capacitance exhibited by operative couplings between the common gate and respective gates of the first portion of paralleled transistor cells of the power semiconductor device, and the second time duration is at least partially responsive to a second resistance or capacitance exhibited by operative couplings between the common gate and respective gates of the second portion of paralleled transistor cells of the power semiconductor device, wherein the first resistance or capacitance is different than the second resistance or capacitance.

Example 15: The method according to Examples 13 and 14, wherein a time duration to turn OFF the power semiconductor device is at least partially responsive to the first time duration and the second time duration.

Example 16: The method according to Examples 13 through 15, wherein the first time duration is at least partially responsive to a first resistance or capacitance exhibited by a gate structure of a first respective transistor cell coupled with the common gate, and the second time duration is at least partially responsive to a second resistance or capacitance exhibited by a gate structure of a second respective transistor cell coupled with the common gate, wherein the first resistance or capacitance is different than the second resistance or capacitance.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

What is claimed is:

1. An apparatus, comprising:
a common drain, a common source, and a common gate, respectively of a power semiconductor device; and
paralleled transistor cells of the power semiconductor device, wherein:
a configuration of a gate structure of a first respective transistor cell coupled with the common gate is different than a configuration of a gate structure of a second respective transistor cell coupled with the common gate; or
a configuration of a first structure coupled between a first portion of the paralleled transistor cells and the common gate is different than a configuration of a second structure coupled between a second portion of the paralleled transistor cells and the common gate.

2. The apparatus of claim 1, wherein the first structure, responsive to the configuration of the first structure, exhibits a first capacitance or resistance, and the second structure, responsive to the configuration of the second structure, exhibits a second capacitance or resistance, and wherein the first capacitance or resistance is different than the second capacitance or resistance.

3. The apparatus of claim 1, wherein the configuration of the first structure comprises a first material and the configuration of the second structure comprises a second material, wherein a resistivity exhibited by the first material is different than a resistivity exhibited by the second material.

4. The apparatus of claim 1, wherein the configuration of the first structure comprises a first shape and the configuration of the second structure comprises a second shape.

5. The apparatus of claim 1, wherein the configuration of the first structure comprises a first dimensions and the configuration of the second structure comprises a second dimensions, wherein at least one of the first dimensions and the second dimensions are different.

6. The apparatus of claim 1, wherein the paralleled transistor cells of the power semiconductor device comprise metal-oxide-semiconductor field-effect transistor cells.

7. The apparatus of claim 1, wherein the paralleled transistor cells of the power semiconductor device comprises silicon-carbide (SiC) transistor cells.

8. The apparatus of claim 7, wherein the SiC transistor cells comprise power metal-oxide-semiconductor field-effect transistor cells.

9. The apparatus of claim 1, wherein the first structure is coupled between the common gate and a gate of a transistor cell of the first portion of the paralleled transistor cells, and the second structure is coupled between the common gate and a gate of a transistor cell of the second portion of the paralleled transistor cells.

10. The apparatus of claim 1, wherein a response of the first structure to a stimulus is different than a response of the second structure to a further stimulus.

11. The apparatus of claim 10, wherein the stimulus is a gate-drain charge of a transistor cell of the first portion of the paralleled transistor cells, and the further stimulus is a gate-drain charge of a transistor cell of the second portion of the paralleled transistor cells.

12. The apparatus of claim 11, wherein the response of the first structure sets a rate-of-change in the gate-drain charge of the transistor cell of the first portion of the paralleled transistor cells, and the response of the second structure sets a rate-of-change in gate-drain charge of the transistor cell of the second portion of the paralleled transistor cells.

13. A method, comprising:
providing a turn OFF signal to a common gate of a power semiconductor device;
turning OFF a first portion of paralleled transistor cells of the power semiconductor device over a first time duration; and
turning OFF a second portion of paralleled transistor cells of the power semiconductor device over a second time duration,
wherein the first time duration is different than the second time duration.

14. The method of claim 13, wherein the first time duration is at least partially responsive to a first resistance or capacitance exhibited by operative couplings between the common gate and respective gates of the first portion of paralleled transistor cells of the power semiconductor device, and the second time duration is at least partially responsive to a second resistance or capacitance exhibited by operative couplings between the common gate and respective gates of the second portion of paralleled transistor cells of the power semiconductor device, wherein the first resistance or capacitance is different than the second resistance or capacitance.

15. The method of claim 13, wherein a time duration to turn OFF the power semiconductor device is at least partially responsive to the first time duration and the second time duration.

16. The method of claim 13, wherein the first time duration is at least partially responsive to a first resistance or capacitance exhibited by a gate structure of a first respective transistor cell coupled with the common gate, and the second time duration is at least partially responsive to a second resistance or capacitance exhibited by a gate structure of a second respective transistor cell coupled with the common gate, wherein the first resistance or capacitance is different than the second resistance or capacitance.
